(19) United States
(12) Patent Application Publication
(10) Pub. No.: US 2007/0289730 A1
(43) Pub. Date: Dec. 20, 2007

(54) Combination heat-transfer plate member

(76) Inventor: Chang-Hsin Wu, Taipo City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/447,125

(22) Filed: Jun. 6, 2006

(51) Int. Cl. H05K 7/20

(52) U.S. Cl. 165/185; 361/705

(57) ABSTRACT

A combination heat-transfer plate member for use with a heat sink to dissipate heat from a CPU is disclosed having a flat graphite base member and two metal sheet members respectively bonded to the top and bottom sides of the flat graphite base member.

### BACKGROUND OF THE INVENTION

1. Field of the Invention

The present invention relates to a heat-transfer plate member for use with a heat sink to dissipate heat from a CPU and more particularly, to a combination heat-transfer plat member, which is comprised of a flat graphite base member and two metal sheet members respectively bonded to the top and bottom sides of the flat graphite base member.

2. Description of the Related Art

Referring to FIGS. 1 and 2, a heat-transfer plate member 3 is shown sandwiched between a CPU 1 and a heat sink 2 for transferring heat from the CPU 1 to the heat sink 2 for dissipation into the outside open air during the operation of the CPU 1. The heat-transfer plate member 3 is a solid copper plate. This design of heat-transfer plate member 3 has the following drawbacks:

1. Because the heat-transfer plate member 3 is made of a solid copper plate, the material cost of the heat-transfer plate member 3 is high.

2. Because the coefficient of heat transfer of copper (402 W/MK) is lower than the coefficient of heat transfer (503 W/MK) of graphite, the heat transferring effect of this design of heat-transfer plate member 3 is not the best.

### SUMMARY OF THE INVENTION

The present invention has been accomplished under the circumstances in view. It is the main object of the present invention to provide a combination heat-transfer plate member, which is inexpensive to manufacture and, provides a satisfactory heat transfer effect. To achieve this and other objects of the present invention, the combination heat-transfer plate member comprises a flat graphite base member, and two metal sheet members respectively bonded to the top and bottom sides of the flat graphite base member with a bonding glue. Preferably, the metal sheet members include one copper sheet member and one aluminum sheet member. The bonding glue can be obtained from silicone rubber adhesive or acrylic rubber adhesive.

### BRIEF DESCRIPTION OF THE DRAWINGS

FIG. 1 is an exploded view showing an application example of a heat-transfer plate member according to the prior art.

FIG. 2 is a sectional assembly view of FIG. 1.

FIG. 3 is an exploded view of a combination heat-transfer plate member in accordance with a first embodiment of the present invention.

FIG. 4 is an elevational view of the combination heat-transfer plate member in accordance with the first embodiment of the present invention.

FIG. 5 is a sectional view in an enlarged scale of the combination heat-transfer plate member in accordance with the first embodiment of the present invention.

FIG. 6 is a sectional view of a combination heat-transfer plate member in accordance with a second embodiment of the present invention.

FIG. 7 is a sectional view of a combination heat-transfer plate member in accordance with a third embodiment of the present invention.

FIG. 8 is a sectional view of a combination heat-transfer plate member in accordance with a fourth embodiment of the present invention.

FIG. 9 is a sectional view of a combination heat-transfer plate member in accordance with a fifth embodiment of the present invention.

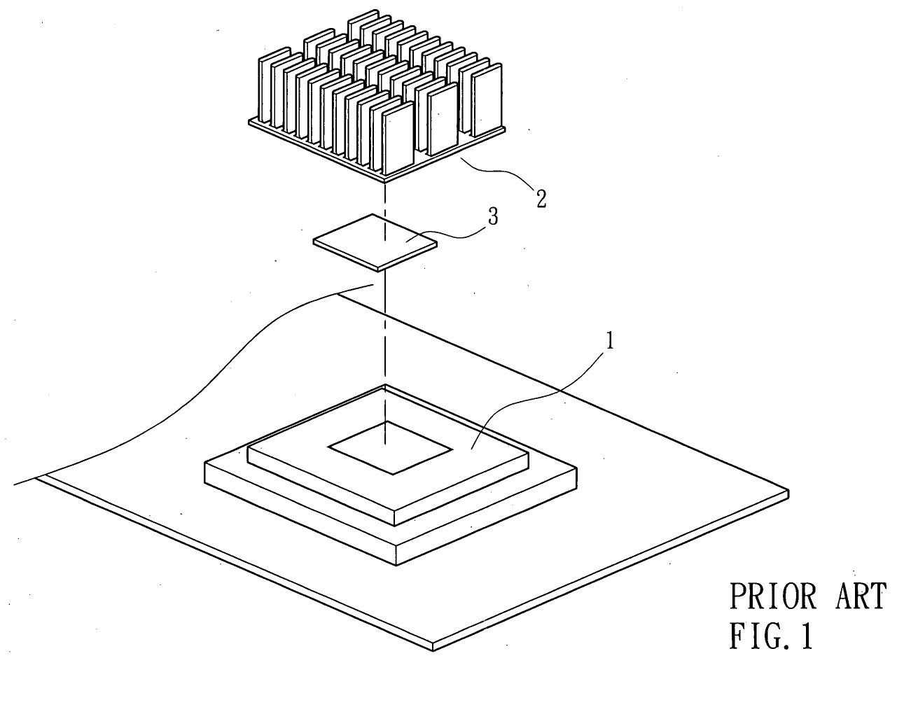

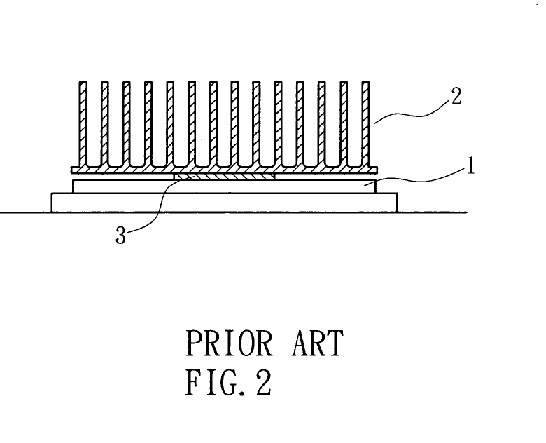

### DETAILED DESCRIPTION OF THE PREFERRED EMBODIMENT

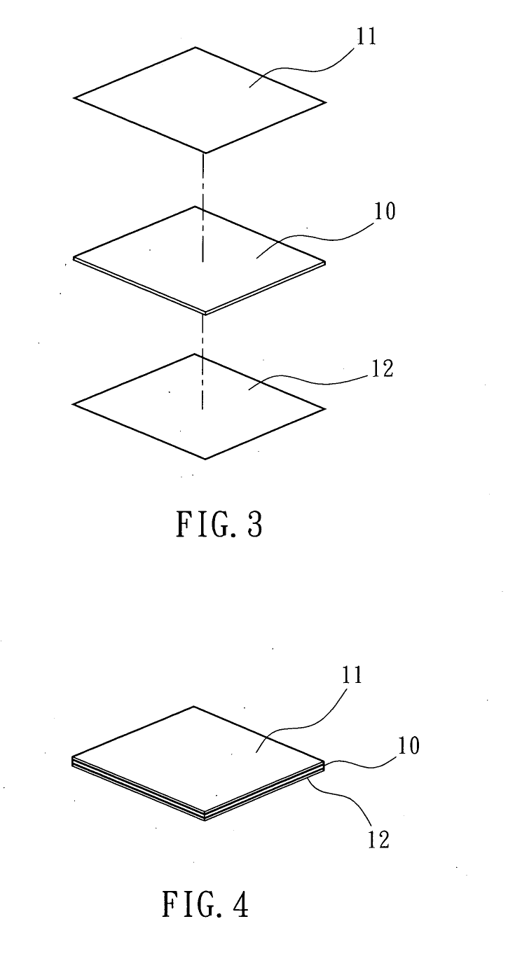

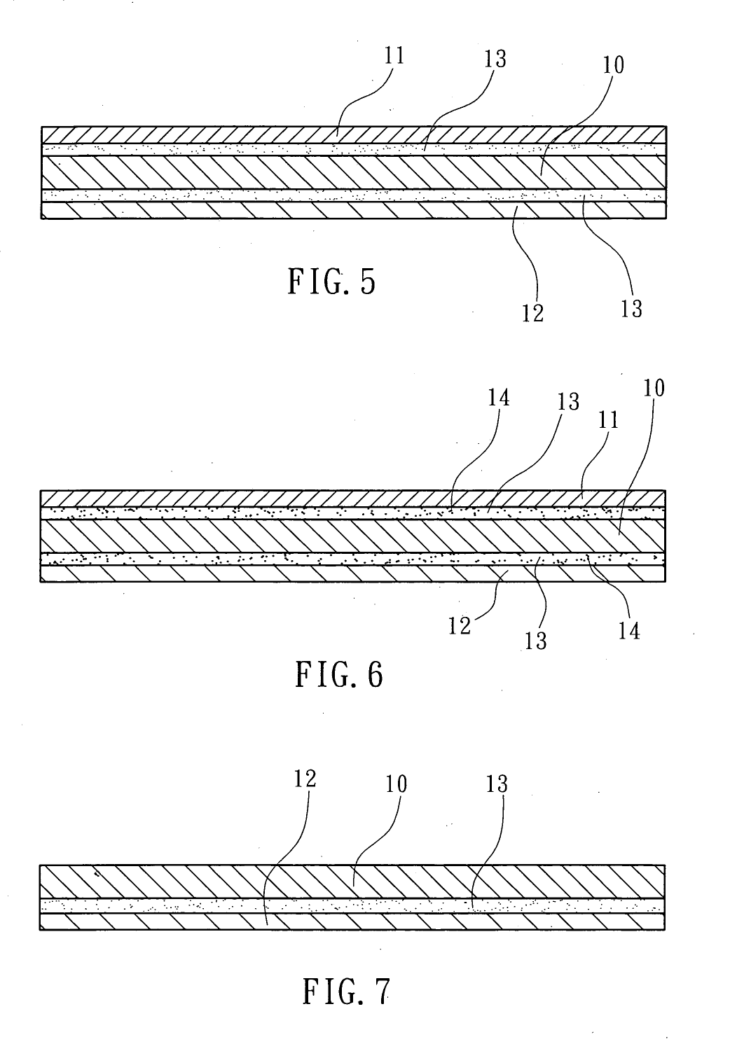

Referring to FIGS. 3˜5, a combination heat-transfer plate member sunscreen assembly in accordance with a first embodiment of the present invention is shown comprising a flat graphite base member 10, a first metal sheet member 11 covered on one side of the flat graphite base member 10, a second metal sheet member 12 covered on the other side of the flat graphite base member 10 opposite to the first metal sheet member 11, and a bonding glue 13 applied to one side of the first metal sheet member 11 and one side of the second metal sheet member 12 and the two opposite sides of the flat graphite base member 10 to fixedly secure the first metal sheet member 11 and the second metal sheet member 12 to the two opposite sides of the flat graphite base member 10.

According to this embodiment, the first metal sheet member 11 is an aluminum sheet member thickness below 0.1 mm, and the second metal sheet member 12 is a copper sheet members of thickness below 0.1 mm. The bonding glue 13 can be silicone rubber adhesive or acrylic rubber adhesive.

FIG. 6 shows a combination heat-transfer plate member in accordance with a second embodiment of the present invention. This embodiment is substantially similar to the aforesaid first embodiment with the exception that a heat-transfer powder 14 is added to the bonding glue 13 to enhance the heat transferring power of the combination heat-transfer plate member. The heat-transfer powder 14 can be graphite powder, carbon powder, copper powder, silver powder, nickel powder, or titanium powder.

FIG. 7 shows a combination heat-transfer plate member in accordance with a third embodiment of the present invention. According to this embodiment, the heat-transfer metal plate member comprises a flat graphite base member 10, a metal sheet member 12 covered on one side of the flat graphite base member 10, and a bonding glue 13 applied to one side of the flat graphite base member 10 and one side of the metal sheet member 12 to fixedly secure the metal sheet member 12 to the flat graphite base member 10.

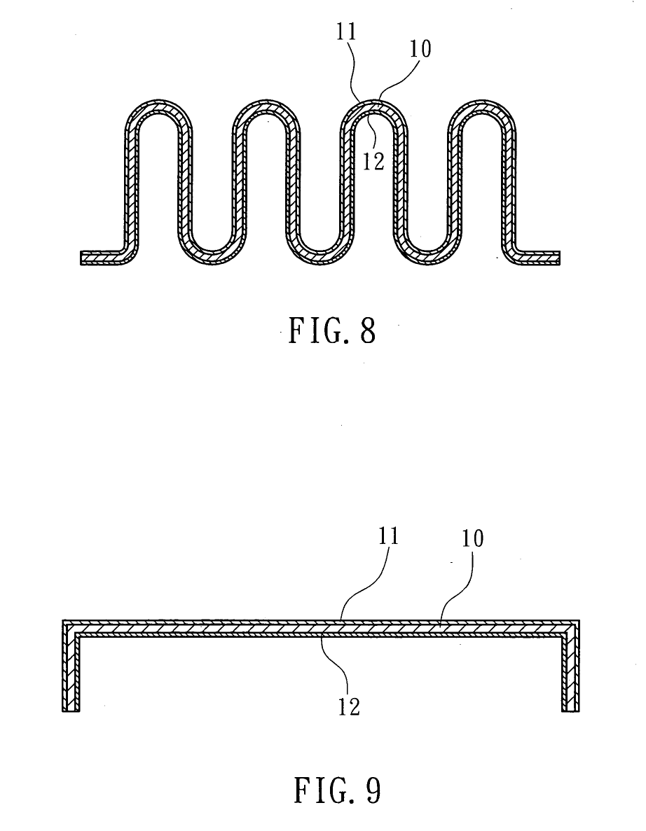

FIG. 8 shows a combination heat-transfer plate member in accordance with a fourth embodiment of the present invention. This embodiment is substantially similar to the aforesaid first embodiment with the exception that the combination heat-transfer plate member of this fourth embodiment has a corrugated profile.

FIG. 9 shows a combination heat-transfer plate member in accordance with a fourth embodiment of the present invention. This embodiment is substantially similar to the aforesaid first embodiment with the exception that the heat-transfer plat member of this fifth embodiment has a substantially U-shaped profile.

As indicated above, a combination heat-transfer plate member in accordance with the present invention has the following benefits:

1. Because the coefficient of heat transfer of copper (503 W/MK) of graphite is higher than the coefficient of heat transfer (402 W/MK) of copper, a combination heat-transfer plate member made according to the present invention is superior to a conventional solid heat-transfer plate member made out of copper or aluminum.

2. During application of the combination heat-transfer plate member, the copper sheet member 12 and the aluminum sheet member are respectively kept in contact with the CPU and the heat sink so that the flat graphite base member 10 effectively absorbs heat energy from the CPU through the copper sheet member 12 and efficiently transfer absorbed heat energy to the heat sink through the aluminum sheet member 11.

3. Because the copper sheet member 12 has a thickness below 0.1 mm and because the material cost of aluminum and graphite is low, the manufacturing cost of the combination heat-transfer plate member is low.

4. Because the aluminum sheet member 11 and the copper sheet member 12 are respectively bonded to the two opposite sides of the flat graphite base member 10, the flat graphite base member 10 is well protected. Therefore, the combination heat-transfer plate member of the present invention has a mechanical strength similar to a heat-transfer plate member of pure copper.

5. Because the flat graphite base member 10 is sandwiched between the aluminum sheet member 11 and the copper sheet member 12, the combination heat-transfer plate member of the present invention can be stamped into any of a variety of curved shapes.

Although particular embodiments of the invention have been described in detail for purposes of illustration, various modifications and enhancements may be made without departing from the spirit and scope of the invention.

What the invention claimed is:

1. A combination heat-transfer plate member comprising a flat graphite base member, at least one metal sheet member covered on at least one of two opposite sides of said flat graphite base member, and a bonding glue applied to said flat graphite base member and said at least one metal sheet member to fixedly secure said at least one metal sheet member to said flat graphite base member.

2. The combination heat-transfer plate member as claimed in claim 1, wherein said at least one metal sheet member each is respectively made out of one of the materials of aluminum and copper.

3. The combination heat-transfer plate member as claimed in claim 1, wherein said bonding glue is selected from one of the materials of silicone rubber adhesive and acrylic rubber adhesive.

4. The combination heat-transfer plate member as claimed in claim 1, wherein said bonding glue is added with a heat-transfer powder.

5. The combination heat-transfer plate member as claimed in claim 4, wherein said heat-transfer powder is a carbon powder.

6. The combination heat-transfer plate member as claimed in claim 4, wherein said heat-transfer powder is a metal powder.
